(19) United States
(12) Patent Application Publication
(10) Pub. No.: US 2025/0266270 A1
(43) Pub. Date: Aug. 21, 2025

(54) SYSTEM AND METHOD FOR NEAR SUBSTRATE GAS DELIVERY

(71) Applicant: Applied Materials, Inc., Santa Clara, CA (US)

(72) Inventors: Andrew ALKAKOS, Santa Clara, CA (US); Imad YOUSIF, San Jose, CA (US); John Anthony O'MALLEY, III, San Jose, CA (US); Santosh S. NESARKAR, Bangalore (IN); Srikantha MALLAPPA, Bangalore (IN); Zhiren LUO, Santa Clara, CA (US)

(21) Appl. No.: 18/443,247

(22) Filed: Feb. 15, 2024

(51) Int. Cl. H01L 21/67; H01L 21/3065

(52) U.S. Cl. CPC H01L 21/67069; H01L 21/3065

(57) ABSTRACT

Disclosed are a gas ring for providing a process gas, a processing chamber having the gas ring, and a gas delivery method. The gas ring includes an annular body surrounding an inner space configured to accommodate a substrate and having a network of gas channels. The network of gas channels includes a plurality of circumferential gas channels coupled with radial gas channels. The plurality of the circumferential gas channels are disposed concentrically around a center of the annular body. The gas ring further includes a plurality of gas inlets and outlets coupled with the network. The gas inlets are disposed along an inner side surface of the annular body. The method includes providing a process gas to the gas ring, flowing the process gas circumferentially and radially along the network of the gas channels, and releasing the process gas via the plurality of gas outlets.

### BACKGROUND

### Field

The present disclosure relates to a system and method for gas delivery to a substrate, and, more specifically, relates to a system configured to provide a near substrate gas delivery.

### Description of the Related Art

In semiconductor processing, a substrate is processed in a chamber filled with process gases. A gas delivery system is used to provide process gases to the chamber. Conventional gas delivery systems may provide process gases from chamber ceiling or from side walls of the chamber. When a conventional gas delivery system that provides process gases from the chamber ceiling is in operation, a center area of a substrate may receive a different flow of the process gas and grow or etch a layer of materials at a different rate compared to the edges of the substrate. As a result, edges of the substrate often experience an uneven growth or removal of material compared to the center of the substrate.

Thus, a need exists for a processing chamber with an improved gas delivery system.

### SUMMARY

Disclosed herein are a gas ring for providing a process gas into a processing chamber, a processing chamber having a gas ring, and a gas delivery method. The gas ring includes an annular body surrounding an inner space configured to accommodate a substrate. The gas ring further includes a network of gas channels disposed within the annular body. The network of gas channels includes a plurality of circumferential gas channels coupled with a plurality of radial gas channels. The plurality of the circumferential gas channels are disposed concentrically around a center of the annular body. The gas ring also includes a plurality of gas inlets coupled with the network of the gas channels; and a plurality of gas outlets coupled with the network of the gas channels and disposed along an inner side surface of the annular body.

In another example, a processing chamber is disclosed that includes a substrate support assembly configured to support a substrate, and a gas delivery system configured to deliver a process gas to the substrate. The gas delivery system includes a gas ring as set forth in the present disclosure.

In yet another example, a gas delivery method is provided. The method provides a process gas into a processing chamber. The gas delivery method includes transferring a substrate into an inner space surrounded by a gas ring that is disposed inside the processing chamber; providing a process gas to a gas inlet of the gas ring, the gas inlet coupled with a network of gas channels disposed within a body of the gas ring; flowing the process gas circumferentially and radially along the network of the gas channels to reach a plurality of gas outlets disposed along an inner side surface of the gas ring and in proximity to an edge of the substrate; and releasing the process gas toward the substrate via the plurality of gas outlets.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present disclosure.

FIG. 2 illustrates a schematic cross-sectional view of a processing chamber having a gas delivery system, according to an embodiment of the present disclosure.

FIG. 3 illustrates a schematic view of the gas delivery system, according to an embodiment of the present disclosure.

FIG. 4 illustrates a schematic perspective view of an installed gas delivery system, according to an embodiment of the present disclosure.

FIG. 5 illustrates a schematic cross-sectional view of a gas ring, according to an embodiment of the present disclosure.

FIG. 6a illustrates a schematic top view of a gas ring, according to an embodiment of the present disclosure.

FIG. 6b illustrates a schematic view of Callout A of the gas ring in FIG. 6a, according to an embodiment of the present disclosure.

FIG. 6c illustrates a cross-sectional view of the gas ring along lines B-B′ in FIG. 6a, according to an embodiment.

FIG. 6d illustrates a cross-sectional view of the upper portion of the gas ring along lines C-C′ in FIG. 6a, according to an embodiment.

FIG. 7 illustrates a schematic bottom view of a gas ring, according to an embodiment of the present disclosure.

FIG. 8 illustrates a gas delivery method, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein is a gas delivery system capable of releasing process gases at locations adjacent to an edge of a substrate disposed in a processing chamber. The gas delivery system includes a gas ring disposed in close proximity to an edge of the substrate. The gas ring includes an annular body surrounding an inner space that is configured to accommodate the substrate. The annular body includes a network of gas channels to distribute process gases from a few gas inlets to a plurality of gas outlets. The plurality of gas outlets are disposed at an inner side surface of the annular body. The plurality of gas outlets are disposed in close proximity to the edges of the substrate, such as within a few inches or centimeters or millimeters away from the edges of a substrate. Thus, the gas delivery system is capable of providing a near substrate gas release. The gas delivery system can increase the uniformity of materials deposited or removed on a substrate, especially at edges of the substrate.

The gas delivery system also includes gas lines configured to couple with the gas ring. The gas lines may enter a processing chamber from side walls or from a bottom section of the processing chamber. The gas lines may be disposed inside other parts, such as a sleeve, for protection.

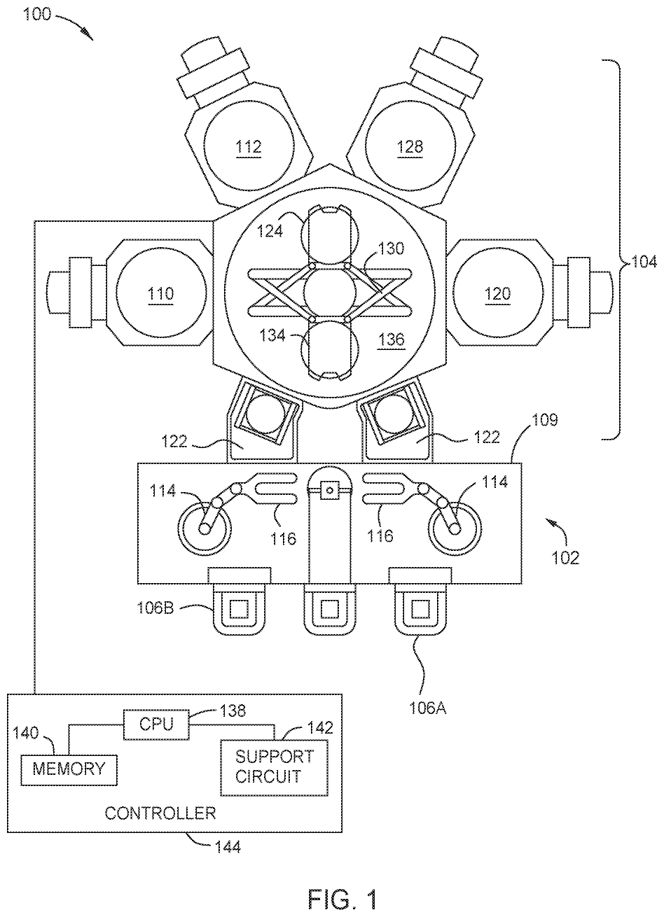

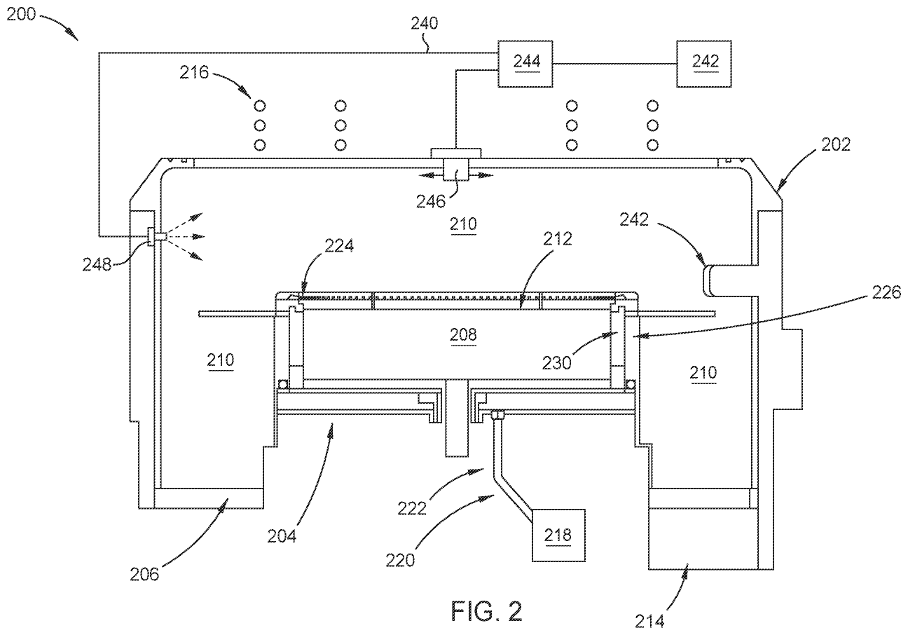

FIG. 1 illustrates a schematic top view of a processing system 100, according to one or more embodiments. According to an embodiment, the processing system 100 includes a gas delivery system 220 (shown in FIG. 2 and other figures) as described in the present disclosure. The processing system 100 includes one or more load lock chambers 122 (two are shown in FIG. 1), a processing platform 104, a factory interface 102, and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, the one or more load lock chambers 122, and a transfer chamber 136 that is coupled to the one or more load lock chamber 122. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122. The gas delivery system 220 can be disposed in one or more of the plurality of processing chambers 110, 112, 120, 128.

In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers.

FIG. 2 illustrates a processing chamber 200 having a gas delivery system 220 according to an embodiment. The processing chamber 200 may be any one of the processing chambers 110, 112, 128, and 120 as shown in FIG. 1. The processing chamber 200 illustrated in FIG. 2 includes chamber walls 202 coupled with a base 206. The processing chamber 200 further includes a substrate support assembly 208 supported by a bottom plate 204 and surrounded by a sleeve 226. A liner 230 is disposed between the sleeve 226 and the substrate support assembly 208 for protection. The chamber walls 202, the base 206, and the bottom plate 204 together enclose a processing region 210. A substrate support assembly 208 is disposed in the processing region 210 and supports a substrate 212 thereon during processing. The chamber walls 202 include at least one substrate transfer port 242 for transferring the substrate 212 in or out of the processing chamber 200. The base 206 includes an exhaust port 214 coupled with a pump (not shown) configured to remove effluent gases from the chamber 200. The chamber 200 may also include a plasma source 216, such as RF coils, configured to energize the process gases in the processing region 210. The plasma source 216 may be disposed along a lid or side walls of the processing chamber 200.

The gas delivery system 220 of the processing chamber 200 is coupled with a plurality of gas sources 218. The gas delivery system 220 provides process gases from the plurality of gas sources 218 into the processing region 210. The gas delivery system 220 is configured to release the process gas at a location adjacent to edges of the substrate 212. According to an embodiment, the location to release the process gas is less than three (3) inches, two (2) inches, one (1) inch, or half (½) inch away from an edge of the substrate 212. The gas delivery system 220 includes a plurality of gas lines 222 and a gas ring 224, which will be described in detail in the following sections of the present disclosure. In one example, gas lines 222 of the gas delivery system 220 enter the processing chamber 200 from the bottom, such as the bottom plate 204 or the base 206, of the processing chamber 200. In another example, gas lines 222 of the gas delivery system 220 may enter the processing chamber 200 from chamber walls 202.

The gas ring 224 may be disposed on the sleeve 226 that surrounds the substrate support assembly 208. The gas ring 224 may additionally couple with a liner 230 of the substrate support assembly 208. The coupling between the gas ring 224 and the liner 230 is configured to prevent process gases from entering between the sleeve 226 and the liner 230. The plurality of gas lines 222 may be disposed in other parts of the processing chamber 200, such as the sleeve 226.

The processing chamber 200 may also include another gas delivery system 240. The gas delivery system 240 is configured to provide process gases into the processing region 210 at locations different from those of the gas delivery system 220. The gas delivery system 240 may be configured to provide a majority of the process gases for processing a substrate, while the gas delivery system 220 functions as an additional tuning knob to fine-tune processing parameters near edges of a substrate. In an embodiment, the gas delivery system 240 includes a gas source 242, a gas splitter 244, a center gas nozzle 246, and one or more side gas nozzles 248. The gas source 242 provides process gases to the gas splitter 244, which splits the process gases into two or more streams and then provides the two or more streams of process gases to the center gas nozzle 246 and the one or more side gas nozzle 248, respectively. The center gas nozzle 246 is disposed inside the processing chamber 200 at a center point above the processing region 210. The one or more side gas nozzles 248 are disposed along side walls of the processing chamber 200. In an embodiment, the gas delivery systems 240 and 220 provide the same process gases to the processing chamber 200, but at different flow rates. Yet in another embodiment, the gas delivery systems 240 and 220 provide different process gases to the processing chamber 200.

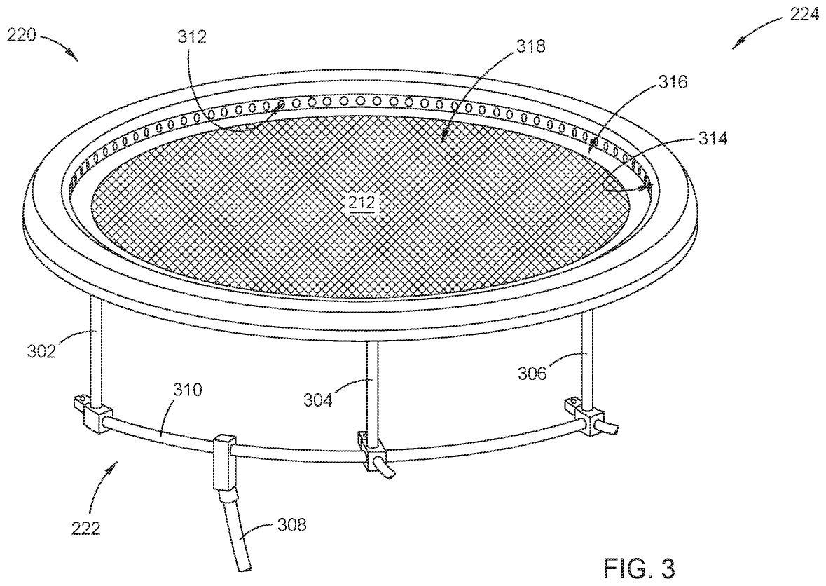

FIG. 3 illustrates a configuration of the gas delivery system 220 according to an embodiment. The gas delivery system 220 includes a plurality of gas lines 222 configured to provide process gases to the gas ring 224. The gas ring 224 surrounds an inner space 318 that accommodates the substrate 212. The plurality of gas lines 222 include a plurality of feed lines 302, 304, and 306 connected with the gas ring 224. The plurality of the feed lines 302-306 may connect with the gas ring 224 at any suitable locations, such as a bottom surface, a side surface, or a top surface of the gas ring. The plurality of gas lines 222 may further include a main line 308 and a distribution line 310. The main line 308 is configured to couple a gas source with the distribution line 310, which distributes the process gas to a plurality of feed lines. According to an embodiment, the main line 308 has a greater diameter than the distribution line 310, which has a greater diameter than the feed lines 302-306. The number of feed lines is not limited to the three (3) feed lines shown in FIG. 3 and can be 6, 12, or any other suitable number. In an embodiment, the gas delivery system 220 includes six (6) feed lines arranged at equal distances along the perimeter of the gas ring 224.

The gas ring 224 is configured to release process gases in close proximity to edges of the substrate 212. The gas ring 224 includes a plurality of gas outlets 312 disposed at an inner side surface 314 of the gas ring 224. The size of the gas ring 224 is configured to be slightly greater than that of the substrate 212. When the gas ring 224 is disposed adjacently to and surrounds the substrate 212, the gas outlets 312 are near the edge 316 of the substrate 212, such as less than a few inches. For example, the gas outlets 312 may be less than three, two, or one inches away from the edge 316 of the substrate 212. The plurality of the gas outlets 312 may be evenly arranged along the entire inner perimeter of the gas ring 224. According to an embodiment, the angular separation between adjacent gas outlets 312 may be less than six (6), three (3), two (2), or one (1) degrees. The gas ring 224 may be made of aluminum, quartz, ceramic or any other suitable material.

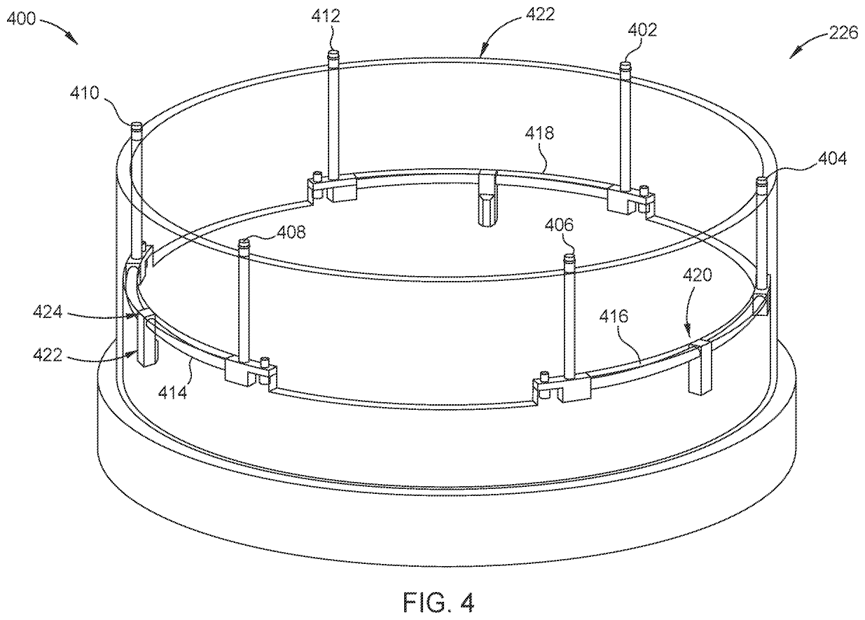

FIG. 4 illustrates a perspective view of a gas delivery system 400 according to an embodiment. The gas delivery system 400 has gas lines that enter the processing chamber 200 from the bottom. The gas delivery system 400 includes six (6) feed lines 402-410 disposed inside the sleeve 226 (shown in FIG. 2). The feed lines 402-410 are vertically arranged. The sleeve 226 has a circular shape. The feed lines 402-410 may be equidistant from each other along the circumference of the sleeve 226. For example, the angular separation between adjacent feed lines may be 60 degrees. The feed lines 402-410 enter the sleeve 226 from a bottom surface 420 and exit at a top surface 422 of the sleeve 226. The distribution lines 414-418 are disposed along the bottom surface 420 of the sleeve 226 and have a shape substantially in conformance with the shape of the sleeve 226. In one example, each distribution line 414, 416, and 418 are coupled with two feed lines such that the process gas is evenly distributed to the two feed lines. In other examples, the distribution line may be coupled with any suitable number of feed lines, such as three (3), four (4), five (5), or even greater number of feed lines. In an embodiment, a stream of a process gas in a delivery line 422 equally splits into two streams at a coupling location 424 where the distribution line 414 is coupled with the delivery line 422. The two streams will flow into the distribution line 414 in opposite directions toward the feed lines 410 and 408.

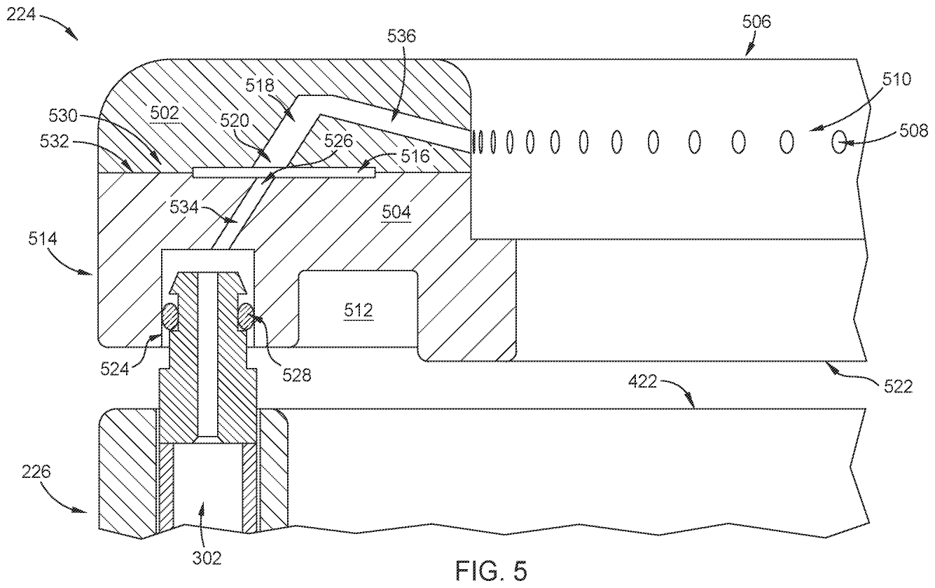

FIG. 5 illustrate a schematic cross-sectional view of the gas ring 224 according to an embodiment. The gas ring 224 includes two portions: an upper portion 502 and a lower portion 504. Each portion has a substantially annular shape. In an embodiment, the upper portion 502 and the lower portion 504 are made of quartz and fused together. The gas ring 224 has a top surface 506, an outer side surface 514, a bottom surface 522, and an inner side surface 510. The gas ring 224 is disposed on a top surface 422 of the sleeve 226. The gas ring 224 is coupled with the feed line 302 to provide process gases into the inner space 318 (shown in FIG. 3) encircled by the gas ring 224.

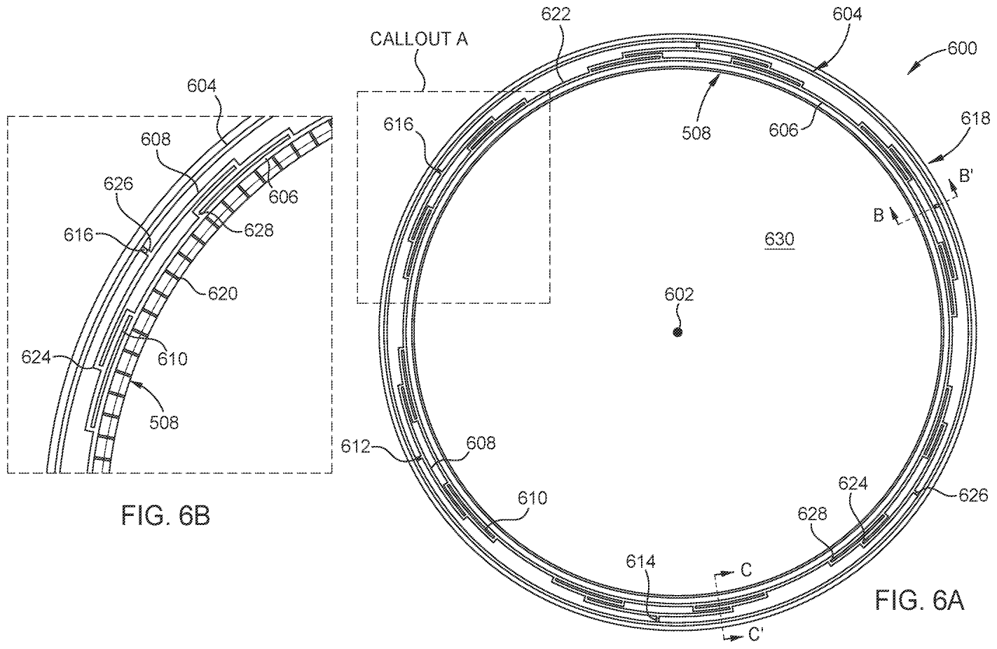

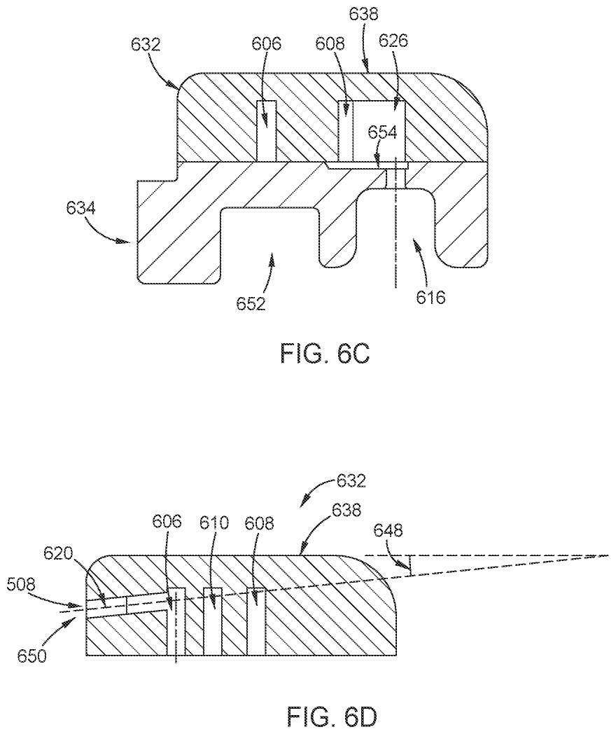

The upper portion 502 includes a plurality of gas outlets 508 disposed at the inner side surface 510. The plurality of gas outlets 508 are distributed to cover the entire inner perimeter of the gas ring 224. A network of gas channels, such as gas channels 622 shown in FIG. 6), is disposed within the gas ring 224 to provide process gases to the plurality of the gas outlets 508. In an embodiment, an upper conduit 518 is coupled with the gas line 302 to provide process gas into the gas outlets 508. The upper conduit 518 includes a gas inlet 520 disposed at a bottom surface of the upper portion 502. The gas inlet 520 is coupled with a gas chamber 516 formed between the upper portion 502 and the lower portion 504. The gas chamber 516 has a greater diameter than that of the gas inlet 520. The upper conduit 518 extend upwardly from the gas inlet 520 in an inwardly slanted direction. A plurality of slanted channels 536 are configured to couple the upper conduit 518 with the plurality of gas outlets 508. In an embodiment, each one of the slanted channel 536 forms an angle with the top surface 506 in the range of between three (3) and ten (10) degrees.

The lower portion 504 includes a gas inlet 524 disposed at a bottom surface 522 and a gas outlet 526 disposed at a top surface 532 of the lower portion 504. A lower conduit 534 is disposed inside the lower portion 504 and extends between the gas inlet 524 and the gas outlet 526. The gas outlet 526 and the gas inlet 520 are aligned to avoid any obstruction of the flow of the process gas. The lower conduit 534 and the upper conduit 518 are coaxially aligned. In an example, the diameter of the upper conduit 518 is greater than that of the lower conduit 534. The lower conduit 534 extends upwardly from the gas inlet 524 in an inwardly slanted direction. In an example, the lower portion 504 includes a groove 512 configured to couple with other parts of the substrate support assembly 208, such as a liner of the sleeve (shown in FIG. 2).

As shown in FIG. 5, the feed line 302 may extend into the gas inlet 524. The inserted portion of the feed line 302 may include a gas seal 528 disposed in a groove to prevent process gases from leaking out of the gas inlet 524.

FIG. 6a illustrates a schematic top view of a gas ring 600 according to an embodiment. FIG. 6b illustrates a schematic configuration of Callout A of the gas ring 600 according to an embodiment. As shown in FIG. 6a, the gas ring 600 has an annular shape with a center 602. The gas ring 600 includes an annular body 618 that surrounds an inner space 630. The annular body 618 includes a channel network 622 of gas channels for providing process gases into the inner space 630. The channel network 622 is configured to split the process gas in a balanced manner from gas feed lines to the gas channels and then to the gas outlets. According to an embodiment, the channel network 622 includes a plurality of circumferential gas channels 604, 606, 608, and 610 configured to distribute process gases along a circumferential direction of the annular body 618. The channel network 622 may also include a plurality of radial gas channels 624, 626, and 628 configured to couple the circumferential gas channels 604, 606, 608, and 610.

According to an embodiment, an outer circumferential gas channel 604 is disposed along an outer perimeter of the annular body 618. The outer circumferential gas channel 604 may form a complete annular channel along the outer perimeter of the annular body 618. The outer circumferential channel 604 is formed within the lower portion 504. According to an embodiment, the plurality of circumferential gas channels 606, 608, and 610 are disposed in the upper portion 502 and have smaller diameters than the gas channel 604.

A plurality of gas inlets 612, 614, and 616 are coupled with the outer circumferential gas channel 604. In an example, the annular body 618 may include six (6) gas inlets. The annular body 618 may include any other number of suitable gas inlets, such as three (3), twelve (12), or thirty six (36) gas inlets. The outer circumferential gas channel 604 can balance the pressure of the process gas distributed by the plurality of gas outlets.

According to an embodiment, an inner circumferential gas channel 606 is disposed along an inner perimeter of the annular body 618. The inner circumferential gas channel 606 may also form a complete annular channel along the inner perimeter of the annular body 618. The inner circumferential gas channel 606 is coupled with a plurality of gas outlets 508 via a plurality of gas channels 620. More detailed descriptions for the configuration among the inner circumferential gas channel and the gas outlet 508 will be provided later in referring to FIG. 6d. The plurality of gas outlet 508 may include 30, 60, 120, 240, 360, 720, or more gas outlets.

The circumferential gas channels 608 and 610 are disposed between the outer circumferential gas channel 604 and the inner circumferential gas channel 606. These intervening circumferential gas channels 608 and 610 include a plurality of channel segments arranged in a recursive and expanding manner. For example, as shown in FIG. 6b, the gas channel 608 is arranged inwardly next to the outer circumferential gas channel 604. In an embodiment, six (6) segments of the gas channel 608 may be evenly distributed along the annular body 618. Each segment may cover approximately thirty degrees along the circumferential direction of the annular body 618. A radial gas channel 626 is disposed at a middle point of a segment of the gas channel 608 and couples the gas channel 608 with the gas inlet 616. At the two ends of the gas channel 608, two radial channels 624 couple the gas channel 608 with the middle points of two segments of the gas channel 610. As a result, the number of segments of the gas channel 610 is twelve (12), which doubles the number of segments of the gas channel 608. At the two ends of the gas channel 610, two radial gas channels 628 couple the gas channel 610 with the inner circumferential channel 606. As a result, the gas channel 608 and 610 spread process gas from one (1) gas inlets 616 disposed on the outer circumferential gas channel 604 to four (4) gas inlets disposed on the inner circumferential gas channels 606. In an embodiment, the angular separation between adjacent gas inlets 616, 612, 614 is 60 degrees, the angular separation between adjacent radial channels 624 is 30 degrees, and the angular separation between adjacent radial channels 628 is 15 degrees.

The annular body 618 further includes a plurality of gas channels 620 couples the inner circumferential gas channel 606 with the plurality of the gas outlets 608. In an example, the plurality of radial channels 620 are substantially oriented toward the center 602. In another example, the plurality of radial channels 624 and 628 may also be oriented toward the center 602.

According to an embodiment, the plurality of circumferential gas channels 604, 606, 608, and 610 are concentric around the center 602. The plurality of circumferential gas channels 604, 606, 608, and 610 are arranged along circles of different diameters, respectively. The size of the plurality of circumferential gas channels may gradually decrease from the outer circumferential channel 604 to the inner circumferential channel 606.

The gas inlets 612, 614, and 616 as shown in FIG. 5, FIGS. 6a, and 6b are disposed along a bottom surface of the annular body 618. The placement of the gas inlets at the bottom surface of the annular body 618 allows a gas delivery line to be embedded in other parts, such as a sleeve, of a processing chamber, as shown in FIG. 4. An embedded gas line is protected by other parts and does not obstruct any flow of the processing as in the processing chamber.

FIG. 6c illustrates a cross-sectional view of the gas ring along lines B-B′ in FIG. 6a, according to an embodiment. FIG. 6a shows an upper portion 632 and a lower portion 634, which may be separately made and then fused together according to an embodiment. Since the lines B-B′ are drawn across a gas inlet, they do not intersect the circumferential gas channel 610. Thus, only the radial gas channel 626, the circumferential gas channel 608, and the inner circumferential channel 606 are shown in FIG. 6c. The radial gas channel 626, the circumferential gas channel 608, and the inner circumferential channel 606 are disposed within the upper portion 632. In an embodiment, the gas channels 606, 608, and 626 have the same height and are substantially perpendicular to a top surface 638 of the upper portion 632.

The lower portion 634 includes the gas inlets 616 coupled with a gas plenum 654. The gas plenum 654 overlaps with the radial channel 626 and the outer circumferential gas channel 604. The lower portion 634 further includes a groove 652 configured to couple with another part of the substrate support assembly, such as a liner. In an embodiment, the lower portion 634 and the upper portion 632 are made of quartz and fused together to make an air-tight seal wherever the two portions contact each other.

FIG. 6d illustrates a cross-sectional view of the upper portion 632 of the gas ring along lines C-C′ in FIG. 6a, according to an embodiment. As the lines C-C′ are drawn across a gas outlet 508 and all circumferential gas channels, FIG. 6d does not show the gas inlet and the radial gas channels. It is noted that the outer circumferential gas channel 604 is disposed within the lower portion 634 and is not shown in FIG. 6d.

As shown in FIG. 6d, the inner circumferential gas channel 606 is disposed in the upper portion 632, as well as the circumferential gas channels 608 and 610. The gas channel 620 couples the gas outlet 508 with the inner circumferential gas channel 606. In an embodiment, the gas channel 620 is slanted downwardly toward the lower portion 634. As a result, the gas channel 620 forms an acute angle 648 with a top surface 638 of the upper portion 632. For example, the gas channel 620 may have a cylindrical shape with an axis 650. The axis 650 forms the acute angle with the top surface 638. The acute angle may be between three (3) and ten (10) degrees.

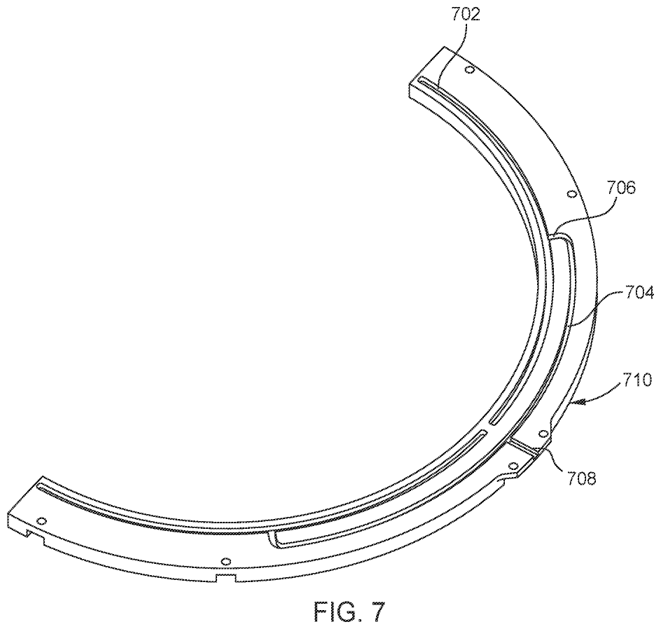

FIG. 7 illustrates a schematic bottom view of an upper portion of an annular body 700 having a gas inlet disposed along an outer side surface, according to an embodiment. Similar with the annular body shown in FIGS. 6a and 6b, FIG. 7 shows an upper portion 700 of an annular body that includes a plurality of circumferential gas channels 702 and 704 coupled with a plurality of radial gas channels 706. The upper portion 700 further includes a gas inlet 708 disposed along an outer side surface 710. When the gas inlet 708 is disposed at the side surface 710, the gas delivery line may go through side walls of the processing chamber and connect directly with the gas inlet 708. The configuration of FIG. 7 may simplify the gas delivery path.

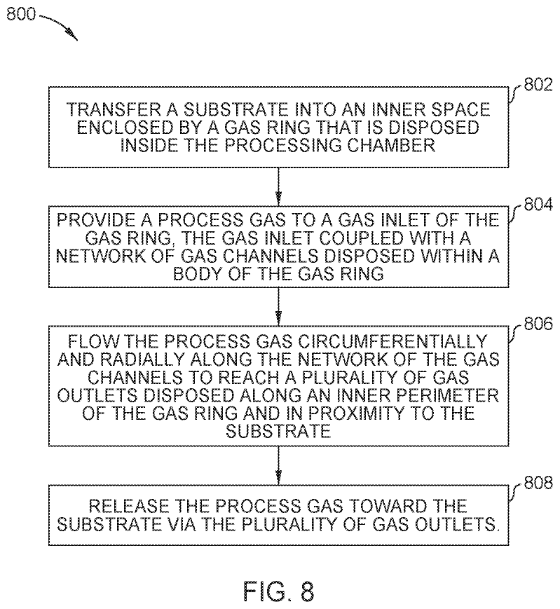

FIG. 8 illustrates a gas delivery method 800, according to an embodiment of the present disclosure. At operation 802, a robotic arm transfers a substrate into a processing chamber and places the substrate on a surface of a substrate support assembly. The surface is located within an inner space surrounded by a gas ring that is disposed inside the processing chamber. At operation 804, the gas lines provide a process gas to a gas inlet of the gas ring. The gas inlet coupled with a network of gas channels disposed within a body of the gas ring. At operation 806, the process gas flows circumferentially and radially along the network of the gas channels to reach a plurality of gas outlets disposed along an inner perimeter of the gas ring and in proximity to the substrate. At operation 808, the process gas is released from the gas ring and flows toward the substrate via the plurality of gas outlets.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A gas ring for providing a process gas into a processing chamber, the gas ring comprising:
an annular body surrounding an inner space configured to accommodate a substrate;
a network of gas channels disposed within the annular body and comprising a plurality of circumferential gas channels coupled with a plurality of radial gas channels, the plurality of the circumferential gas channels being disposed concentrically around a center of the annular body;
a plurality of gas inlets coupled with the network of the gas channels; and
a plurality of gas outlets coupled with the network of the gas channels and disposed along an inner side surface of the annular body.

2. The gas ring of claim 1, further comprising a plurality of slanted channels coupling the plurality of the gas outlets with the network of gas channels and forming an acute angle with a top surface of the annular body.

3. The gas ring of claim 1, wherein the plurality of the circumferential gas channels comprise an inner circumferential gas channel disposed along an inner perimeter of the annular body and forming a circle.

4. The gas ring of claim 3, wherein the plurality of the circumferential gas channels comprise an outer circumferential gas channel disposed along an outer perimeter of the annular body and forming a circle.

5. The gas ring of claim 1, wherein the plurality of the radial gas channels extend radially toward the center of the annular body.

6. The gas ring of claim 5, wherein the plurality of the circumferential gas channels comprise a plurality of segments, and the plurality of the radial gas channels are coupled to an end or a middle point of each segment.

7. The gas ring of claim 1, wherein the plurality of the gas inlets are evenly disposed along an outer side surface of the annular body, or the plurality of the gas inlets are evenly disposed along a bottom surface of the annular body.

8. The gas ring of claim 1, wherein the annular body comprises an upper portion coupled with a lower portion.

9. The gas ring of claim 8, wherein the plurality of the gas outlets are disposed on the upper portion.

10. The gas ring of claim 8, wherein the plurality of the circumferential gas channels comprise an inner circumferential channel disposed within the upper portion.

11. The gas ring of claim 8, wherein the lower portion comprises the plurality of the gas inlets and a plurality of conduits coupling the plurality of the gas inlets with the network of the gas channels.

12. The gas ring of claim 11, wherein the annular body comprises a gas chamber formed between the upper portion and the lower portion, and the plurality of the conduits are coupled with the gas chamber.

13. The gas ring of claim 8, wherein the lower portion further comprises a groove disposed at a bottom surface of the lower portion and configured to couple with another part of the processing chamber.

14. The gas ring of claim 1, wherein the plurality of the gas outlets are configured to release the process gas at locations less than three (3) inches away from an edge of the substrate.

15. A processing chamber for processing a substrate, the processing chamber comprising:
a substrate support assembly configured to support a substrate; and
a gas delivery system configured to deliver a process gas to the substrate, wherein the gas delivery system comprises a gas ring comprising:
an annular body surrounding an inner space for accommodating the substrate;
a network of gas channels disposed within the annular body and comprising a plurality of circumferential gas channels coupled with a plurality of radial gas channels, the plurality of the circumferential gas channels being disposed concentrically around a center of the annular body;
a plurality of gas inlets coupled with the network of the gas channels; and
a plurality of gas outlets coupled with the network of the gas channels and disposed along an inner surface of the annular body.

16. The processing chamber of claim 15, wherein the substrate support assembly comprises a liner configured to protect the substrate support assembly, and the gas ring is coupled with the liner.

17. The processing chamber of claim 15, wherein the substrate support assembly comprises a sleeve, and the gas delivery system comprises a plurality of gas lines disposed within the sleeve.

18. The processing chamber of claim 15, wherein the gas delivery system comprises a plurality of gas lines coupled with the gas ring along an outer side surface of the annular body.

19. The processing chamber of claim 15, wherein the plurality of the circumferential gas channels extend along a circumferential direction of the annular body, and the plurality of the radial gas channels extend radially toward the center of the annular body.

20. A gas delivery method for providing a process gas into a processing chamber, the method comprising:
transferring a substrate into an inner space surrounded by a gas ring that is disposed inside the processing chamber;
providing a process gas to a gas inlet of the gas ring, the gas inlet coupled with a network of gas channels disposed within a body of the gas ring;
flowing the process gas circumferentially and radially along the network of the gas channels to reach a plurality of gas outlets disposed along an inner side surface of the gas ring and in proximity to an edge of the substrate; and
releasing the process gas toward the edge of the substrate via the plurality of gas outlets.
